(19) United States
(12) Patent Application Publication
(10) Pub. No.: US 2010/0315781 A1
(43) Pub. Date: Dec. 16, 2010

(54) ANTI-GRAVITY THERMOSYPHON HEAT EXCHANGER AND A POWER MODULE

(75) Inventor: Bruno AGOSTINI, Dietikon (CH)

Correspondence Address: BUCHANAN, INGERSOLL & ROONEY PC, POST OFFICE BOX 1404, ALEXANDRIA, VA, 22313-1404, US

(73) Assignee: ABB Research Ltd, Zurich (CH)

(21) Appl. No.: 12/796,713

(22) Filed: Jun. 9, 2010

(30) Foreign Application Priority Data
Jun. 10, 2009 (EP) 09162370.2

(51) Int. Cl. H05K 7/20; F28D 15/02

(52) U.S. Cl. 361/700; 165/104.21; 165/104.28; 165/110

(57) ABSTRACT

A thermosyphon heat exchanger according to the disclosure includes a set of linear conduit elements and a heat exchange plate mounted in a heat receiving region on the conduit elements. The longitudinal axes of the conduit elements extend in a first direction in a plane defined by the flat side of the heat exchange plate. The conduit elements project above the heat receiving region in the first direction on a first side and an opposing second side such that the extension of the conduit elements on each side of the heat exchange region is suitable for constituting a condensing region for condensing a refrigerant vaporized in the heat receiving region if the first direction is arranged vertically.

### RELATED APPLICATIONS

This application claims priority under 35 U.S.C. §119 to European Patent Application No. 09162370.2 filed in Europe on Jun. 10, 2009, the entire content of which is hereby incorporated by reference in its entirety.

### FIELD

The disclosure relates to an anti-gravity thermosyphon heat exchanger and a power module including an anti-gravity thermosyphon heat exchanger.

### BACKGROUND INFORMATION

Known thermosyphon heat exchangers can include a heat receiving region at a bottom side of the thermosyphon heat exchanger for vaporizing a refrigerant and a condensing region at an upper side for condensing the vaporized refrigerant ascended to the condensing region. Some power electronic devices mounted on the thermosyphon heat exchanger can be mounted upside-down, for example in traction applications. Thus, either the power electronic device has to be re-mounted upside-down on the thermosyphon or cost-intensive anti-gravity thermosyphon heat exchanger have to be used to allow a flexible orientation of the power electronic devices. In the former, the re-mounting process can be time and cost intensive and contains a risk of damaging the expensive power electronic devices. Sometimes the power electronic modules are fixed to the thermosyphon heat exchanger so that an easy re-mounting of the power electronic module is not possible. In the latter, anti-gravity thermosyphon heat exchangers are very expensive, because of the use of special coatings in the conduit elements to move the refrigerant by capillary forces instead of gravity.

U.S. Pat. No. 7,665,511 discloses an orientation insensitive thermosyphon. The disclosed thermosyphon shows a boiling chamber for vaporizing the refrigerant and two separate sets of conduit elements each extending from the boiling chamber in an angle of about 45° to the plane of the two major axes of the boiling chamber. Thus, the thermosyphon with the mounted power electronic device can be turned to 90° such that the power electronic device can be mounted on the bottom side of the boiling chamber and the thermosyphon still works with gravity and without any capillary forces. A disadvantage of this thermosyphon can be that it needs a large mounting space and can be difficult to fix because of the differently oriented planes of the thermosyphon. In addition, the construction of the thermosyphon can be complicated, expensive and instable, because each set of conduit elements, which extend remarkably over the boiling chamber to guarantee effective condensing, has to be fixed to the boiling chamber and produce high leverage forces on the fixing point at the boiling chamber.

### SUMMARY

A thermosyphon heat exchanger is disclosed which includes at least one set of linear conduit elements. At least one heat exchange plate is mounted in a heat receiving region of the linear conduit elements. Longitudinal axes of the linear conduit elements are arranged in a first direction running through or being parallel to a plane defined by the heat exchange plate. The at least one set of linear conduit elements extends beyond the heat receiving region on a first side and on an opposing second side in the first direction such that an extension of the at least one set of linear conduit elements on one of the first and second sides of the heat receiving region constitutes a condensing region for condensing a refrigerant vaporized in the heat receiving region in one of the first or second side that is arranged higher than the extension on the other side with respect to the direction of gravity in an operating state of the thermosyphon heat exchanger. The extension of the other side constitutes a liquid reservoir.

A power module is disclosed which includes at least one heat emitting device and at least one thermosyphon heat exchanger. The thermosyphon heat exchanger includes at least one set of linear conduit elements. At least one heat exchange plate is mounted in a heat receiving region of the linear conduit elements. Longitudinal axes of the linear conduit elements are arranged in a first direction running through or being parallel to a plane defined by the heat exchange plate. The at least one set of linear conduit elements extends beyond the heat receiving region on a first side and on an opposing second side in the first direction such that an extension of the at least one set of linear conduit elements on one of the first and second sides of the heat receiving region constitutes a condensing region for condensing a refrigerant vaporized in the heat receiving region in one of the first or second side that is arranged higher than the extension on the other side with respect to the direction of gravity in an operating state of the thermosyphon heat exchanger. The extension of the other side constitutes a liquid reservoir. The at least one heat emitting device is thermally connected to the at least one heat exchange plate.

### BRIEF DESCRIPTION OF THE DRAWINGS

In the following, first and second exemplary embodiments are described on the basis of the drawings. The drawings show:

FIG. 1 is a schematic, three-dimensional illustration of a first exemplary embodiment of the thermosyphon heat exchanger;

FIG. 2 is a cross-sectional view of the heat exchange plate of the first exemplary embodiment of the thermosyphon heat exchanger;

FIG. 3 is a cross-sectional view of heat exchange plates of a variation of the first exemplary embodiment of the thermosyphon heat exchanger;

FIG. 4 is a schematic illustration of the first exemplary embodiment of the thermosyphon heat exchanger according to the disclosure showing the three-dimensional position within a coordinate system;

FIG. 5 is a schematic illustration of the first exemplary embodiment of the thermosyphon heat exchanger according to the disclosure showing a first exemplary inclination within the x-z plane of the coordinate system;

FIG. 6 is a schematic illustration of the first exemplary embodiment of the thermosyphon heat exchanger according to the disclosure showing a second exemplary inclination within the x-z plane of the coordinate system;

FIG. 7 is a schematic illustration of the first exemplary embodiment of the thermosyphon heat exchanger according to the disclosure showing an exemplary inclination within the x-y plane of the coordinate system;

FIG. 8 is a schematic illustration of a second exemplary embodiment of the thermosyphon heat exchanger according to the disclosure showing the three-dimensional position within a coordinate system;

FIG. 9 is a schematic illustration of the exemplary second embodiment of the thermosyphon heat exchanger according to the disclosure showing an exemplary inclination within the x-y plane of the coordinate system; and

FIG. 10 is a schematic illustration of a heat exchange plate of the second exemplary embodiment.

### DETAILED DESCRIPTION

An orientation insensitive thermosyphon heat exchanger is disclosed which is, for example, easy to mount and includes a basic, inexpensive and stable construction and requires little mounting space.

The exemplary thermosyphon heat exchanger includes at least one set of linear conduit elements including at least one linear conduit element and at least one heat exchange plate mounted in a heat receiving region on the conduit elements. The term linear shall not be understood in a narrow sense as to be strictly straight only. Geometrical variations, such as curves, for example, shall be included as long as the function is not detrimentally affected. The longitudinal axes of the conduit elements extend in a first direction running through or being parallel to a plane defined by the biggest side, referred to in the following as a flat side, of the heat exchange plate. The conduit elements exceed over, for example extend beyond, the heat receiving region in the first direction on a first side and a second side opposing the first side, such that the extension of a set of linear conduit elements on one of the first or second sides of the heat receiving region constitutes a condensing region for condensing a refrigerant vaporized in the heat receiving region if this first or second side is arranged higher than the extension on the other side with respect to the direction of gravity in an operating state. The extension of the other side constitutes a liquid reservoir. That means each of the extensions can be suitable for constituting a condenser region for condensing a refrigerant vaporized in the heat receiving region if the first direction is arranged vertically and the function of each extension depends on the orientation of the heat exchanger.

An exemplary power module includes at least one heat emitting device and one thermosyphon heat exchanger with at least one heat exchange plate as described above. The at least one heat emitting device can be thermally connected to the at least one heat exchange plate.

The exemplary thermosyphon heat exchanger can be mounted even with a 180° rotation of the thermosyphon heat exchanger together with the power electronic modules mounted thereon, because after the rotation, the extension of the conduit elements before on the bottom side can be rotated on the top side of the heat receiving region. Thus, in both positions there exists a top extension of the conduit elements for condensing the vaporized refrigerant. There is no need for expensive anti-gravity thermosyphons using capillary forces. In addition, the conduit elements extend on both sides of the heat receiving region only in the first direction and thereby, the exemplary thermosyphon has a flat construction and can be easy to mount at the application place and does not need much space.

In one exemplary embodiment, the extension on the first side and the extension on the second side can be arranged symmetrically to a symmetry axis of the thermosyphon heat exchanger. In one exemplary embodiment, this symmetry axis can be perpendicular to the first direction and runs in the direction of the arrangement of the conduit elements. The region of the extension of the conduit elements suitable for condensing can have the same size on both sides of the heat receiving region. By rotating the thermosyphon 180° around the third axis being perpendicular to the first direction and the direction of the conduit elements-arrangement, the condensing region, for example the extension of the conduit elements at the top side of the heat receiving region, can remain equal. The same advantages apply, if the heat receiving region is arranged in the middle between first ends of the conduit elements and second ends of the conduit elements.

In one exemplary embodiment, the set of linear conduit elements can include at least a first manifold, connecting first ends of the conduit elements, and a second manifold connecting second ends of the conduit elements. The easy and efficient way of construction by a plurality of conduit elements arranged between two manifolds can provide a stable and cheap base construction of a thermosyphon. In a further exemplary embodiment, each manifold can have a closable opening for filling and/or discharging the refrigerant. The closable opening of the first manifold can be point symmetrical to the center of the thermosyphon heat exchanger to the closable opening of the second manifold. Thus, upon rotating the thermosyphon 180°, the first opening can be at the place of the second opening before and the thermosyphon has the same form. Therefore, the mounting space reserved for the thermosyphon and its opening does not to be changed upon rotation of the thermosyphon. The center of the thermosyphon refers to the center point of the plane of the first direction and the direction in which the conduit elements are arranged.

In another exemplary embodiment, the thermosyphon heat exchanger can have fixing devices for fixing the thermosyphon heat exchanger. The fixing devices can be arranged point symmetric to a center point of the thermosyphon heat exchanger. This can be especially advantageous in combination with the point symmetrical arrangement of closable openings.

In an exemplary embodiment, the conduit elements can have multiport extruded tubes so that inexpensive, stable and effective conduit elements from the automotive sector can be used.

In an exemplary embodiment of the thermosyphon heat exchanger, when first ends of the conduit elements are arranged at a higher position compared to second ends of the conduit elements or contrariwise, the thermosyphon heat exchanger can be filled with the refrigerant such that the conduit elements in the heat receiving region are filled with the refrigerant and the extension of the conduit elements on the upper side of the heat receiving region remains empty. Therefore, the upper extension of the conduit elements, irrespective of which extension actually points upwards, can work as a condenser for the vaporized refrigerant.

In one exemplary embodiment, the heat exchange plate can be soldered to the conduit elements. For heat exchange plates soldered to the conduit elements, it can be advantageous for the heat exchange plate to be soldered in the middle of the thermosyphon such that the orientation of the thermosyphon can be changed by rotation. If the position of the heat exchange plate is easy changeable, the power electronic device can be rotated together with heat exchange plate and could be remounted in the new orientation. But a soldered heat exchange plate has better heat transportation characteristics such that a solution for an orientation insensitive thermosyphon heat exchanger is needed.

The heat exchange plate can be is connected to all conduit elements to achieve maximum heat transportation from the heat exchange plate to the conduit elements.

The conduit elements can be continuous from the extension on the first side of the heat receiving region to the second side. This has the advantage that the construction of the thermosyphon heat exchanger can be stable and optimal vapor and refrigerant transportation characteristics can be achieved by continuous conduit elements.

In another exemplary embodiment of the disclosure, the thermosyphon heat exchanger can have a second set of linear conduit elements. The longitudinal axes of the conduit elements of the second set can be arranged in a second direction in, or parallel, to the plane. This can have the advantage that despite two sets of linear conduit elements the construction space in the direction rectangular to the plane is not increased remarkably. In addition, the cooling performance of the thermosyphon heat exchanger can be improved for all states of rotation of the thermosyphon heat exchangers within the plane of the heat exchange plate, because there are two sets of conduit elements with different angles to the vertical direction. In one exemplary embodiment the second direction can be rectangular to the first one. This can further improve the cooling performance, because at least one set of conduit elements can always be arranged in an angle less than 45° to the vertical direction.

In another exemplary embodiment, the described crossed arrangements of two sets of linear conduit elements can be efficiently and easy achieved by rectangular crossing two simple thermosyphon heat exchangers with only one set of linear conduit elements. The crossing region corresponds to the region of the heat exchange plates of both thermosyphon heat exchangers. The heat exchange plates can be thermally connected. This can increase the produced number of simple thermosyphon heat exchanger and can save production costs.

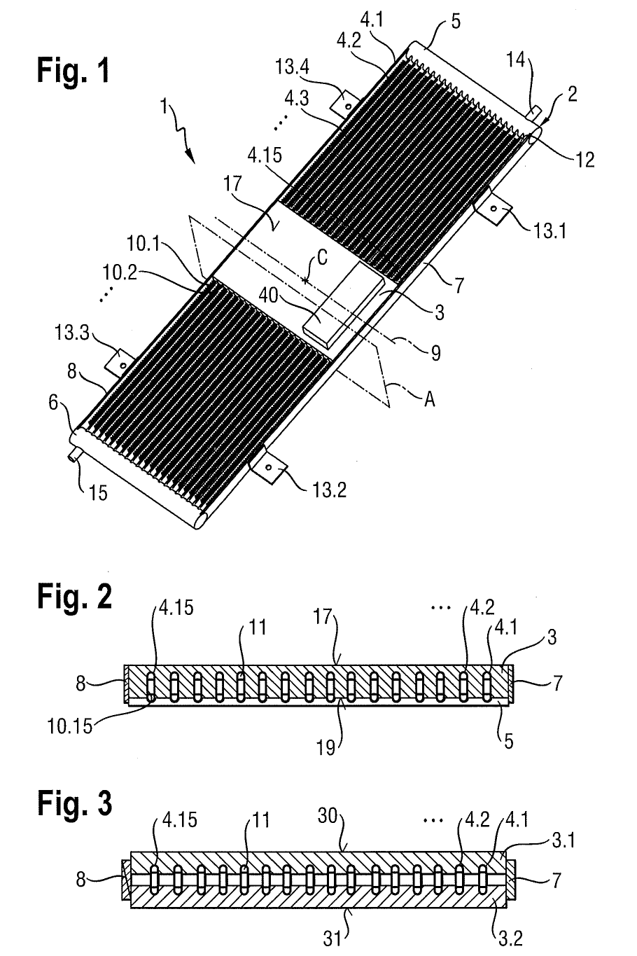

FIG. 1 shows a three-dimensional view on an exemplary inventive thermosyphon heat exchanger 1. The exemplary thermosyphon heat exchanger 1 includes one set 2 of multiport extruded tubes 4.1 to 4.15 as conduit elements and a heat exchange plate 3 mounted on the set 2 of multiport extruded tubes 4.1 to 4.15. The multiport extruded tubes 4.1 to 4.15 within the set 2 can be arranged within a plane. The set 2 of multiport extruded tubes 4.1 to 4.15 comprises as well two manifolds 5 and 6. The multiport extruded tubes 4.1 to 4.15 are arranged between the first manifold 5 and the second manifold 6.

The manifolds 5 and 6 are circular cylinders which can be arranged in parallel. The multiport extruded tubes 4.1 to 4.15 can be arranged perpendicular to the cylinder axes of the manifolds 5 and 6 at the circular outer walls of the manifolds 5 and 6. The rectangular arrangement does not restrict the disclosure because even another angular arrangement can be possible but the rectangular arrangement can be especially stable and space-saving. The longitudinal axis of each multiport extruded tube 4.1 to 4.15 extends in a first direction. The longitudinal axes of the manifolds 5 and 6 extend in a second direction, in the exemplary embodiment, perpendicular to the first direction.

The multiport extruded tubes 4.1 to 4.15 within the set 2 can be arranged in one single row and parallel to each other. The set 2 can be additionally stabilized by the frame elements 7 and 8 which can be mounted on the ground areas of the cylinders of the manifolds 5 and 6 or at the circular walls next to the ground areas of the cylinders of the manifolds 5 and 6. This arrangement does not restrict the disclosure. An alternative set can have different rows of multiport extruded tubes 4.1 to 4.15, wherein each row can contain parallel several multiport extruded tubes 4.1 to 4.15. In exemplary embodiments, each pair of multiport extruded tubes 4.1 to 4.15 is arranged to be parallel, for example, the longitudinal axis of each multiport extruded tube 4.1 to 4.15 within one set is elongated along the first direction.

Each of the multiport extruded tubes 4.1 to 4.15 can be linear and continuous. Each of the multiport extruded tubes 4.1 to 4.15 includes several separated sub-tubes which open at the first and second end of the multiport extruded tubes 4.1 to 4.15. The construction of the multiport extruded tube 4.1 to 4.15 by several sub-tubes has an advantage that a maximum contact surface between the refrigerant and the multiport extruded tubes 4.1 to 4.15 can be established. Also, a thick multiport extruded tube with several sub-tubes can be more stable than a number of thin, individual tubes. The multiport extruded tubes 4.1 to 4.15 can be connected to the manifolds 5 and 6 such that the openings of the sub-tubes of the multiport extruded tubes 4.1 to 4.15 at their first and second ends open into the first and second manifold 5 and 6, respectively, and that no refrigerant liquid or vapor can leak the closed cooling circuit.

The heat exchange plate 3 can be connected to the multiport extruded tubes 4.1 to 4.15 in a heat receiving region of the set 2 of multiport extruded tubes 4.1 to 4.15 in the middle between the manifolds 5 and 6, for example, by soldering. The heat receiving region can be substantially identical to the region covered by the heat exchange plate 3 in a plane spanned by the first and second direction. In the exemplary embodiment, the heat exchange plate 3 can be arranged on the multiport extruded tubes 4.1 to 4.15 such that each multiport extruded tube 4.1 to 4.15 projects the heat exchange plate 3 on a first side of the heat exchange plate 3 in the same manner as on a second side of the heat exchange plate. The first side of the heat exchange plate 3 refers to a side facing the first manifold 5 and the second side to a side facing the second manifold 6. Since the multiport extruded tubes 4.1 to 4.15 are linear and continuous, the first and second sides oppose each other. Each multiport extruded tube 4.1 to 4.15 extends the heat exchange plate 3 on both sides with the same length and the same angle, for example, 90°. For example, the multiport extruded tubes 4.1 to 4.15 between the first side and the first manifold 5 have the same length as between the second side and the second manifold 6. Therefore, when the first direction is arranged as a vertical direction and for example, the first manifold 5 can be the top manifold, rotating the thermosyphon heat exchanger 1 180° around a center point C of the thermosyphon does not change the size of the region between the top side of the heat exchange plate 3 and the top manifold. In this example, the top manifold before rotation is manifold 5 and after rotation it is manifold 6. Thus, the exemplary embodiment always has a similar condensing region, for example the region between a top manifold and the heat receiving region, upon rotation of the thermosyphon heat exchanger 1. The region between the first manifold 5 and the first side can be arranged symmetrically to a symmetry axis 9 to the region between the second manifold 6 and the second side.

The region between the first manifold 5 and the heat receiving region could, in another exemplary embodiment, even be smaller than the region between the second manifold 6 and the heat exchange plate 3. The smaller region can still be suitable to cool down and condense the vaporized refrigerant. The size of such a condensing region depends for example, on the heat amount produced by the power electronic device to be cooled down and by the characteristics of the refrigerant, on the cooling characteristics of the multiport extruded tubes 4.1 to 4.15 in the condensing region and on the power of any external cooling fans. Such a non-symmetric division of the extensions of the multiport extruded tubes on both sides of the heat exchange plate 3 can be advantageous for power cooling devices which are only rarely mounted upside-down or for cooling devices which need a lower cooling power if mounted upside-down.

Any device to be cooled down can be mounted on the heat exchange plate 3. The exemplary thermosyphon heat exchanger 1 can be especially convenient for power electronic modules or power electric modules which are normally soldered to the heat exchange plate 3 for an optimal heat transport. For example, one heat emitting device 40 is shown. FIG. 2 shows a cross-sectional view A of the thermosyphon heat exchanger 1 at the height of the heat exchange plate 3. The heat exchange plate 3 can have grooves 10.1 to 10.15 each in a shape corresponding to the shape of the profile and in the same arrangement of the multiport extruded tubes 4.1 to 4.15 such that the heat exchange plate 3 can be easily plugged with the grooves 10.1 to 10.15 on the first multiport extruded tubes 4.1 to 4.15 and soldered thereon. The grooves 10.1 to 10.15 can have approximately the same depth as the first multiport extruded tubes 4.1 to 4.15 such that a maximum contact surface of the multiport extruded tubes 4.1 to 4.15 with the surface of the heat exchange plate 3 in the grooves 10.1 to 10.15 can be established and the grooves 10.1 to 10.15 surround the first multiport extruded tubes 4.1 to 4.15 on three sides. The meaning of surrounding in this application and in the context of the grooves 10.1 to 10.15 can include not only the encasing of the multiport extruded tubes 4.1 to 4.15 by the grooves 10.1 to 10.15 but also, for example, the encompassing of the first multiport extruded tubes 4.1 to 4.15 with the maximum contact to them which still allows the plugging of the heat exchange plate 3 on the multiport extruded tubes 4.1 to 4.15. The encasing has the drawback that once the heat exchange plate 3 is mounted on the multiport extruded tubes 4.1 to 4.15, it cannot be taken off without taking off one of the cylinders 5 or 6. But the encasing still increases the contact surface between the heat exchange plate 3 and the multiport extruded tubes 4.1 to 4.15. The heat exchange plate 3 can be soldered to the multiport extruded tubes 4.1 to 4.15 to establish optimal heat conductivity from the heat exchange plate 3 to the multiport extruded tubes 4.1 to 4.15 or to the refrigerant within them, respectively.

FIG. 2 shows the parallel arrangement of the multiport extruded tubes 4.1 to 4.15. The profile of the multiport extruded tubes 4.1 to 4.15 can be basically rectangular, wherein the smaller sides of the rectangle are formed circular here. The flat sides can be larger than the circular sides and the multiport extruded tubes 4.1 to 4.15 can be arranged in parallel to each other such that the larger sides face each other to guarantee maximum space between the multiport extruded tubes 4.1 to 4.15. This infers high cooling air flow speeds and a maximum surface for the air flow to pass. This is important for the region where the heat exchange plate 3 is not mounted. The flat sides of the multiport extruded tubes 4.1 to 4.15 can have approximately the same size as the cylinder-diameter of the manifolds 5 and 6 or a little bit smaller. The thickness, for example, the size of the smaller side, of the profile of the multiport extruded tubes 4.1 to 4.15 can be chosen regarding the cooling requirements, available cooling power of the cooling air flow and the properties of the refrigerant in a liquid and vaporized state. The properties of the refrigerant determine as well the form, number and size of the sub-tubes 11 in the multiport extruded tubes 4.1 to 4.15.

FIG. 1 shows cooling fins 12 in the region between the first manifold 5 and the first side of the heat exchange plate 3 and between the second manifold 6 and the second side between neighbored multiport extruded tubes 4.1 to 4.15 and between the marginal multiport extruded tubes 4.1 and 4.15 and the frame elements 7 and 8, respectively. The cooling fins can increase the surface of the multiport extruded tubes 4.1 to 4.15 with whom they are in direct thermal contact. Thus, the heat of the vaporized refrigerant can be more efficiently transported from the condensing region to the ambiance by convection. A cooling air flow is created either artificially by a cooling fan or naturally by an air flow created by temperature differences between the ambiance and the air between the multiport extruded tubes 4.1 to 4.15.

The thermosyphon heat exchanger 1 can have fixing elements 13.1 to 13.4 arranged at the frame elements 7 and 8. In this exemplary embodiment, the fixing elements are angle brackets. One bracket arm can be fixed at the frame element 7 or 8 and the other bracket arm has a hole. The thermosyphon heat exchanger 1 can be fixed by screws, bolts or other fixation means through the hole to a fixing wall or a fixing mechanism adapted to the arrangement of the fixing elements 13.1 to 13.4. In the exemplary embodiment, the arrangement of the fixing elements 13.1 to 13.4 can be point symmetric to the center point C, which is in the middle between the ends of the multiport extruded tubes 4.1 to 4.15 and in the middle between the two frame elements 7 and 8 or in the middle between the marginal multiport extruded tubes 4.1 and 4.15.

The exemplary thermosyphon heat exchanger 1 can have two refrigerant connections 14 and 15 as closable opening for filling and discharging the thermosyphon 1 with the refrigerant. The first refrigerant connection 14 can be arranged in the first direction as a projecting connection on the side of the circular wall of the first manifold 5 being opposite to the connections of the multiport extruded tubes 4.1 to 4.15 at the first manifold 5. Known thermosyphon heat exchangers have only one refrigerant connection, such that in a fixed position, the refrigerant can either be filled in or be discharged. For example, if the refrigerant connection would be only at a top manifold, a known thermosyphon could be fixed and filled with refrigerant, but cannot be discharged in a mounted state. If the known thermosyphon heat exchanger is mounted upside-down, the thermosyphon has to be filled before fixing it, because the refrigerant connection would be upon rotation at the bottom manifold. Therefore, two refrigerant connections have the advantage that the exemplary thermosyphon heat exchanger 1 can be filled and discharged while being fixed in any of its operational directions. The refrigerant connections 14 and 15 can be arranged such that they are symmetric to the center point C. Thus, the first refrigerant connection 14 arrives after the rotation of the thermosyphon around 180° around the center point at the place of the second refrigerant connection 15 before the rotation. Therefore, space for the refrigerant connections 14 and 15 in a fixing space does not have to be changed upon fixing the thermosyphon heat exchanger 1 in an upside-down position.

In the exemplary embodiment, the complete thermosyphon heat exchanger 1 can be constructed symmetrical to the center point C in the plane of the first and second direction such that the thermosyphon heat exchanger 1 upon rotation of about 180° around the center point C can have the same characteristics as before the rotation. Exemplary characteristics are for example, the size, the borderline, the functionality, the fixing positions of the thermosyphon heat exchanger 1, the positions of the refrigerant connections 14 and 15 and the position, size and design of the regions between the sides of the heat exchange plate 3 and the manifolds 5 and 6, respectively.

A mounting position of the exemplary thermosyphon heat exchanger 1 can be such that the first direction is a vertical direction which means that gravity force points in the same direction as the first direction. But the disclosure is not restricted by the this mounting direction. The first direction can be any angle except 90° and 270° from the vertical direction because one of the two manifolds 5 and 6 could be arranged at a higher position, with respect to the vertical direction, than the other manifold. In such a fixed position, the thermosyphon heat exchanger 1 can be filled by the top refrigerant connection with the refrigerant until the bottom manifold, the multiport extruded tubes 4.1 to 4.15 in the region between the bottom manifold and the bottom side of the heat exchange plate 3 and in the heat receiving region is filled with refrigerant. The multiport extruded tubes 4.1 to 4.15 remain empty in the region between top side of the heat exchange plate 3 and the top manifold and even the top manifold remains empty. Then, the top refrigerant connection can be closed such that a closed cooling circuit is achieved. If the thermosyphon heat exchanger 1 would be remounted in an upside-down position, the refrigerant filling level fulfils the same condition as described above.

FIG. 3 shows an alternative embodiment of the first embodiment with respect to the heat exchange plate 3. In the alternative embodiment on two sides of the set 2 of multiport extruded tubes 4.1 to 4.15 with respect to the plane of the multiport extruded tubes 4.1 to 4.15, a first and a second heat exchange plate 3.1 and 3.2 are mounted on the multiport extruded tubes 4.1 to 4.15. Each of the first and second heat exchange plate 3.1 and 3.2 can have on one side grooves which have a profile like the profile of the multiport extruded tubes 4.1 to 4.15 of the set 2. The first heat exchange plate 3.1 can be bonded with the grooves to a first side of the set 2 of multiport extruded tubes 4.1 to 4.15 with respect to the plane of the set 2 such that all multiport extruded tubes 4.1 to 4.15 enter in the corresponding grooves of the first heat exchange plate 3.1. Each multiport extruded tube 4.1 to 4.15 enters at maximum half the dimension of the multiport extruded tube 4.1 to 4.15 in the groove such that at least another half of the multiport extruded tube 4.1 to 4.15 is not surrounded by the first heat exchange plate 3.1. The other half of the multiport extruded tubes 4.1 to 4.15 can be at least partly entered into the grooves of the second heat exchange plate 3.2. Thus, the thermosyphon heat exchanger of the alternative embodiment offers mounting surfaces 30 and 31 on two sides of the set 2.

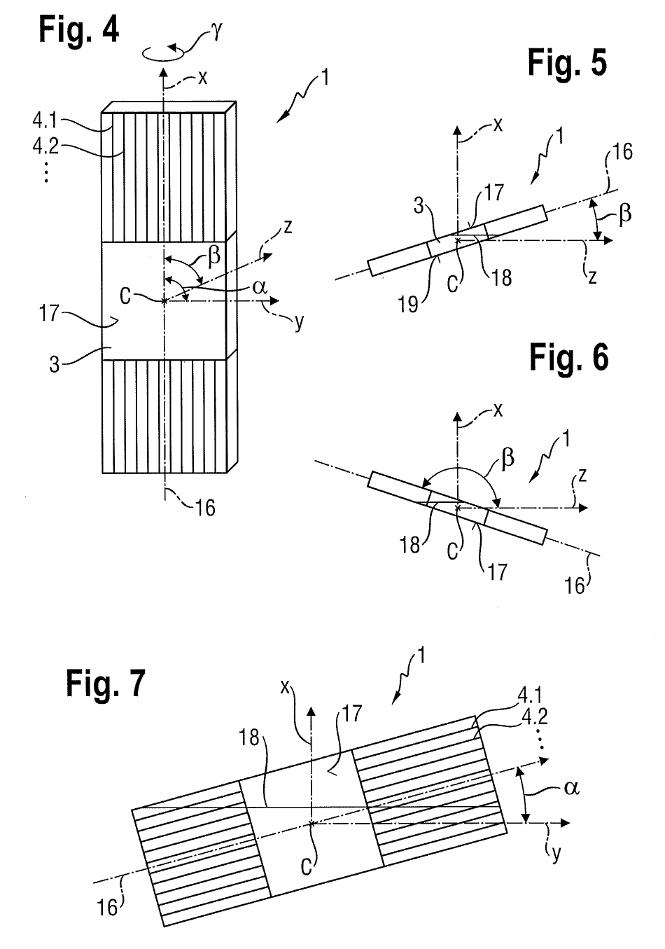

FIG. 4 shows a schematic illustration of the first exemplary embodiment of the disclosure, however less detailed than in FIG. 1. FIG. 4 shows a three-dimensional Cartesian coordinate system with the three directions x, y and z. The coordinate systems are fixed and defined such that the x-direction points against the gravitation. FIG. 4 illustrates the position of the exemplary thermosyphon heat exchanger 1 of the first embodiment in the three-dimensional space. The longitudinal axis 16 of the exemplary thermosyphon heat exchanger 1, illustrated by dash-dotted line, points in the first direction, i.e. in the direction of the longitudinal axes of all multiport extruded tubes 4.1 to 4.15 of the set 2, and passes the center point C. The center point C coincides with the origin of the coordinate system and is the point of rotation of the exemplary thermosyphon heat exchanger 1. The longitudinal axis 16 even coincides in the illustrated position of FIG. 4 with the x-direction of the coordinate system, shown by a dashed line. The angle α is the angle between the vertical direction and the projection of the longitudinal axis on the x-y-plane. The angle β is the angle between vertical direction and the projection of the longitudinal axis 16 on the x-z-plane. The angle γ is the angle of rotation of the exemplary thermosyphon heat exchanger 1 around the x-axis.

In the illustrated example, α and β are 90° and γ is here defined as 0°, but the following description can apply accordingly to all angles of γ. If the exemplary thermosyphon heat exchanger 1 is inclined out of the plane defined by the flat side of the heat exchange plate from the vertical direction to a horizontal direction, i.e. decreasing β versus 0° or increasing β versus 180°, the refrigerant in the exemplary thermosyphon heat exchanger 1 can partly flow from the heat receiving region into the condensing region, which is the upper extension of the multiport extruded tubes 4.1 to 4.15. FIGS. 5 and 6 show an exemplary inclination in the x-z-plane with β smaller than 90° and β larger than 90°, respectively and α equal 90° and illustrate the level 18 of the liquid refrigerant in the thermosyphon heat exchanger 1. In this example in FIG. 5, without restriction of the disclosure, the mounting surface 17 of the heat exchange plate 3 for mounting power electronic devices points in the negative z-direction.

Consequently, if the angle β is decreased as shown in FIG. 5, the exemplary thermosyphon heat exchanger 1 is inclined such that the side 19 opposing the mounting surface 17 points versus the ground and approaches there with decreasing angles β. Thus, the liquid refrigerant next to the mounting surface 17, in the upper region of the heat exchange plate 3 can flow into the bottom part of the condensing region. At a certain angle β next to 0° the parts of the power electronic devices mounted in the parts of the mounting surface 17 that are not in contact with the liquid refrigerant enlarges such that the power electronic devices cannot be efficiently cooled down any more. However, for the major part of the angular region β, the thermosyphon heat exchanger 1 works well. The same can hold for angles β between about 270° and about 360°, because of the symmetry of the exemplary thermosyphon heat exchanger 1.

If the angle β is increased as shown in FIG. 6, the exemplary thermosyphon heat exchanger 1 is inclined such that mounting surface 17 aligns versus the ground and approaches there with decreasing angles β. Thus, the mounting surface 17 is always in contact with the refrigerant, because the liquid refrigerant flows from the opposing side 19 of the heat exchange plate 3 into the bottom part of the condensing region. Consequently, the angle β can be increased almost to 0°. However at 0°, the exemplary thermosyphon heat exchanger 1 malfunctions as well, because the vaporized refrigerant cannot rise to the condensing region being at the same gravitational potential level. The same can hold for angles β between about 180° and about 270°, because of the symmetry of the exemplary thermosyphon heat exchanger 1.

A problem can be the inclination of the exemplary thermosyphon heat exchanger 1 such that the thermosyphon heat exchanger 1 is rotated within the plane defined by the flat side of the heat exchange plate 3, for example, varying angle α. FIG. 7 shows an exemplary inclination with a smaller than 90° and β equal 90° in the x-y-plane and illustrates the level 18 of the liquid refrigerant in the exemplary thermosyphon heat exchanger 1. If α is decreased, the liquid refrigerant can flow from the upper part of the heat receiving region and even from the bottom extension region filled with liquid refrigerant into the condensing region. Thus, the smaller the angle α becomes, the effective condensing region, for example, the top extension part not flooded with liquid refrigerant, decreases and the effective heat receiving region of the heat exchange plate 3, for example, the region of the heat exchange plate 3 having filled multiport extruded tubes 4.1 to 4.15, decreases. Therefore, the cooling performance can decrease, when at a certain angle β, a power electronic device is not in thermal contact with liquid refrigerant and as a result the performance for the power electronic device can decrease. Therefore, thermosyphon heat exchanger 1 according to the first exemplary embodiment of the disclosure can be operated between 10° and 90° or between 90° and 170° or between 190° and 350° with respect to the angle α.

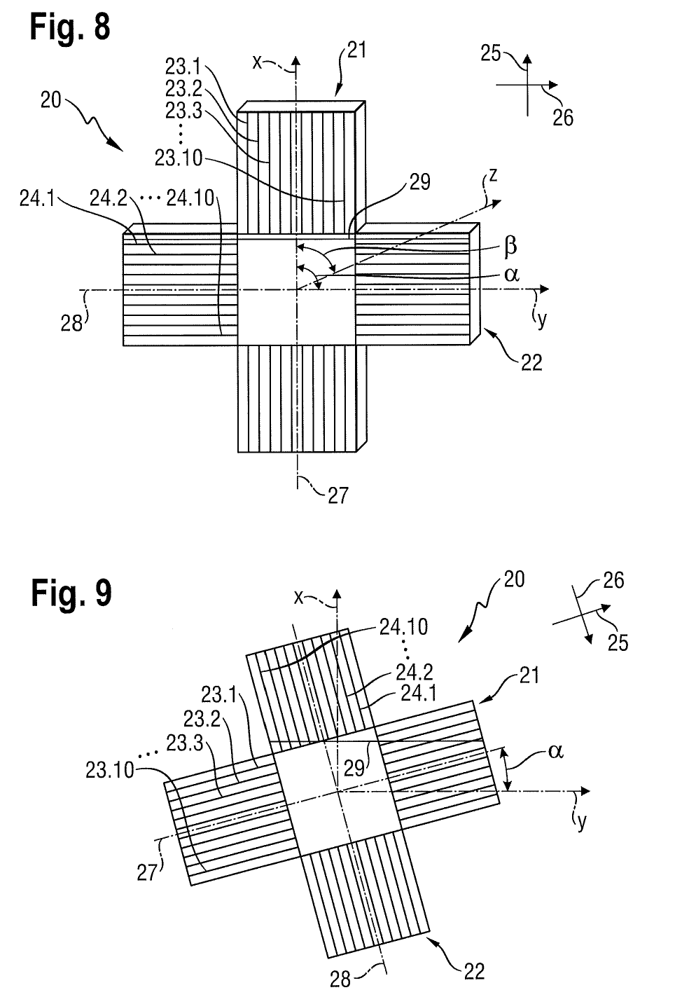

FIGS. 8 and 9 illustrate an exemplary thermosyphon heat exchanger 20 according to a second embodiment of the disclosure. The exemplary thermosyphon heat exchanger 20 includes a first set 22 of multiport extruded tubes 23.1 to 23.10 and a second set 23 of multiport extruded tubes 24.1 to 24.10. Each set 21 and 22 can be designed as the set 2 of the first exemplary embodiment of the disclosure including manifolds, fins, refrigerant connections, fixing devices, etc. The multiport extruded tubes 23.1 to 23.10 or 24.1 to 24.10 within one set 21 or 22 are arranged with their longitudinal axes in parallel. The multiport extruded tubes 23.1 to 23.10 of the first set 21 can be arranged in a first plane and their longitudinal axes are a ligand in a first direction 25. Thus, the first set 21 has a longitudinal axis 27 aligned in the same direction as the longitudinal axis of the multiport extruded tubes 23.1 to 23.10. The multiport extruded tubes 24.1 to 24.10 of the second set 22 can be arranged in a second plane parallel to and neighboring the first plane and their longitudinal axes are aligned in a second direction 26. Thus, the second set 22 has a longitudinal axis 28 aligned in the same direction as the longitudinal axis of the multiport extruded tubes 24.1 to 24.10. The second direction 26 is perpendicular to first direction and parallel to the first and second plane. The two sets 21 and 22 can be arranged such that there is a crossing region and four equally sized regions of extensions projecting over the crossing region. Each region of extension can be suitable for condensing vaporized refrigerant if the extension is a top part of a set having a longitudinal axis aligned in a vertical direction, here the upper part of the set 21.

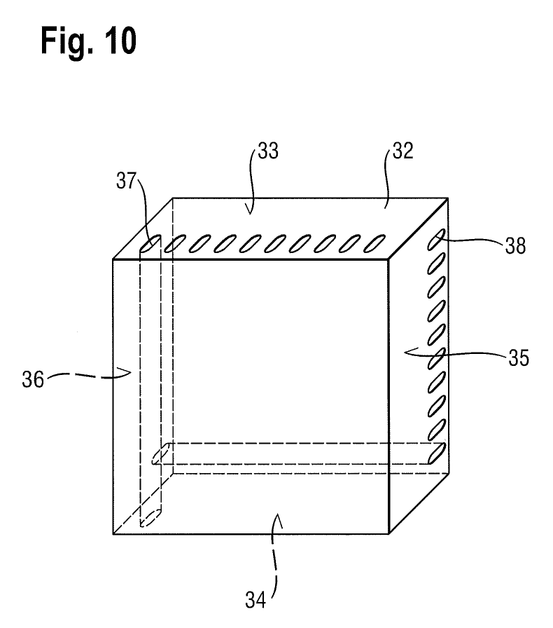

Both sets 21 and 22 can be thermally connected via a common heat exchange plate 32 as illustrated in FIG. 10. The heat exchange plate 32 can have a number of first holes 37 linearly extending from a first side 33 to a second side 34. The heat exchange plate 32 can have a number of second holes 38 linearly extending from a third side 35 to a fourth side 36. The profile of the holes 37 and 38 corresponds to the profile of the multiport extruded tubes 23.1 to 23.10 and 24.1 to 24.10. The number of holes and their arrangement correspond to the number of multiport extruded tubes 23.1 to 23.10 or 24.1 to 24.10 of the set 22 or 23 and their arrangement within the set 22 or 23. Thus, the first holes 37 hold the multiport extruded tubes 23.1 to 23.10 and the second holes 38 hold the multiport extruded tubes 24.1 to 24.10. The flat side of the heat exchange plate 32 can be quadratic.

In an alternative embodiment, each set 21 and 22 of multiport extruded tubes has a heat exchange plate mounted corresponding to the heat exchange plate 3 mounted on the set 2. Since the heat exchange plates are each mounted in the middle of the respective set 21 and 22, the heat exchange plates can both be in the crossing region of the two sets 21 and 22. The heat exchange plates can have quadratic flat sides, such that the crossing region can be covered by both heat exchange plates. The heat exchange plates can be thermally connected by thermal grease for example. Alternatively, the heat exchange plates can be soldered to each other. The thermal connection between the heat exchange plates can be improved by heat pipes.

FIG. 8 shows the position of the exemplary thermosyphon heat exchanger 20 according to the second embodiment of the disclosure in the x-y-z coordinate system introduced in FIG. 3. Accordingly, the angles α and β define the same angles of inclination with respect to the first longitudinal axis 27 of the first set 21. In the illustrated position, the first longitudinal axis 27 aligned in a vertical direction and the second longitudinal axis 28 in a horizontal direction. The angles α and β are, for example, 90° and the thermosyphon heat exchanger 20 can be filled up in this position until the complete heat receiving region, here identical with the crossing region, is filled up until level 29 with liquid refrigerant. Consequently, in this position the 3 regions of extensions can be filled up with liquid refrigerant and only the upper extension is empty and suitable for condensing vaporized refrigerant. For example, the horizontally arranged set 22 of multiport extruded tubes 24.1 to 24.10 can be filled up with liquid refrigerant, while the vertically arranged set 21 of multiport extruded tubes 23.1 to 23.10 can be filled up with liquid refrigerant only in the bottom region of extension and in the crossing region.

Upon inclining the thermosyphon heat exchanger 20 within the plane formed by the first and second direction, for example, increasing or decreasing α, liquid refrigerant moves from the horizontally arranged set 22 from the side of the set 22 which rises upon rotation into the empty condensing region of the vertically arranged set 21 which rotates out of the vertically position upon rotation. FIG. 9 shows the decrease of the angle α, for example, a clockwise rotation. Upon rotation, the set 21 moves to be aligned in a horizontal orientation and the set 22 moves to be aligned in a vertical orientation such that after rotation of the thermosyphon heat exchanger 20 about 90° the set 22 is vertically arranged and the set 21 is horizontally arranged. Therefore, the cooling performance of the exemplary thermosyphon heat exchanger 20 does not decrease upon rotation in the plane of the heat exchange plates as in the first embodiment of the disclosure. The multiport extruded tubes 23.1 to 23.10 and 24.1 to 24.10 within the heat receiving region remain always filled with liquid refrigerant. At least one set 21 or 22 of multiport extruded tubes 23.1 to 23.10 or 24.1 to 24.10 or its longitudinal axis has an angle of 45° or less relative to the vertical direction such that an effective flow of the vaporized refrigerant into the empty parts of this set 21 or 22 can take place.

It is noted that in the second exemplary embodiment, the longitudinal axis of the second set 22 and the longitudinal axis of the manifold of the set 21 can both be aligned in the second direction 26. It is also possible that the longitudinal axis of the second set 22 point in the second direction and the longitudinal axis of the manifold of the set 21 can be aligned in a third direction.

The FIGS. 3 to 9 show only schematically the disclosure. For example the level 18 or 29 of liquid refrigerant illustrates the level of refrigerant within the multiport extruded tubes 23.1 to 23.10 or 24.1 to 24.10 or 4.1 to 4.15. Even formulations for example, like “the heat receiving region, the heat exchange plate, the condensing region, the crossing region or the extension is filled with liquid refrigerant or is empty” refer not to the whole region but only to the inner volume of the multiport extruded tubes 23.1 to 23.10 or 24.1 to 24.10 or 4.1 to 4.15 in said regions.

The material of the heat exchange plate 3, the manifolds 5, 6 and the multiport extruded tubes can be, for example, aluminium, any aluminium alloy or another material which combines good heat conduction properties with small weight.

All geometric descriptions of arrangements are not restricted to the mathematical exact definition but also include the impreciseness of production and arrangements which nearly correspond to the described arrangements.

The vertical direction can be the direction along or against the gravitation force.

The disclosure is not restricted to the described embodiments. All embodiments described are combinable with each other. A exemplary embodiment does not restrict the disclosure to the exemplary embodiment, alternatives or combinations with other embodiments are included in the scope of protection.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. A thermosyphon heat exchanger, comprising,
at least one set of linear conduit elements;
at least one heat exchange plate mounted in a heat receiving region of the linear conduit elements, whereby longitudinal axes of the linear conduit elements are arranged in a first direction running through or being parallel to a plane defined by the heat exchange plate and wherein the at least one set of linear conduit elements extends beyond the heat receiving region on a first side and on an opposing second side in the first direction such that an extension of the at least one set of linear conduit elements on one of the first and second sides of the heat receiving region constitutes a condensing region for condensing a refrigerant vaporized in the heat receiving region in one of the first or second side that is arranged higher than the extension on the other side with respect to a direction of gravity in an operating state of the thermosyphon heat exchanger and wherein the extension of said other side constitutes a liquid reservoir.

2. Thermosyphon heat exchanger according to claim 1, wherein the heat receiving region is arranged about midway between first ends of the linear conduit elements and second ends of the linear conduit elements.

3. Thermosyphon heat exchanger according to claim 1, wherein the at least one set of linear conduit elements comprises a plurality of linear conduit elements, wherein an longitudinal axis of each linear conduit element of the at least one set of linear conduit elements is arranged in the first direction.

4. Thermosyphon heat exchanger according to claim 1, wherein the at least one set of linear conduit elements comprises at least a first manifold connecting first ends of the linear conduit elements and a second manifold connecting second ends of the linear conduit elements.

5. Thermosyphon heat exchanger according to claim 4, wherein each manifold has a closable opening for filling and/or discharging the thermosyphon heat exchanger by the refrigerant and the closable opening of the first manifold is arranged about a point symmetrical, about a center (C) of the thermosyphon heat exchanger, to the closable opening of the second manifold.

6. Thermosyphon heat exchanger according to claim 1, wherein the thermosyphon heat exchanger has fixing devices for fixing the thermosyphon heat exchanger, the fixing devices being arranged symmetrically to a center point (C) of the thermosyphon heat exchanger.

7. Thermosyphon heat exchanger according to claim 1, wherein the linear conduit elements are multiport extruded tubes.

8. Thermosyphon heat exchanger according to claim 1, wherein when first ends of the linear conduit elements are arranged at a higher level in a vertical direction compared to the corresponding second ends of the linear conduit elements or second ends of the linear conduit elements are arranged at a higher level in a vertical direction compared to first ends of the linear conduit elements, the thermosyphon heat exchanger is filled with the refrigerant such that the linear conduit elements in the heat exchanger region are filled with the refrigerant and the extension of the linear conduit elements on the upper side of the heat receiving region remains empty and suitable for condensing the vaporized refrigerant.

9. Thermosyphon heat exchanger according to claim 1, comprising a further set of linear conduit elements, wherein a longitudinal axis of the linear conduit elements of the further set is arranged in a second direction in or parallel to said plane.

10. Thermosyphon heat exchanger according to claim 9, wherein the second direction extends transversely to the first direction, substantially perpendicular to the first direction.

11. Thermosyphon heat exchanger according to claim 9, wherein the further set of linear conduit elements is thermally connected to the heat exchange plate in a crossing region of the set of linear conduit elements and the further set of linear conduit elements.

12. Thermosyphon heat exchanger according to claim 9, wherein the linear conduit elements of at least one of the sets of linear conduit elements and/or of the further set of linear conduit elements is continuous from the extension on the first side of the heat receiving region to the second side.

13. Power module, comprising:
at least one heat emitting device; and
at least one thermosyphon heat exchanger, the thermosyphon heat exchanger, comprising,
at least one set of linear conduit elements;
at least one heat exchange plate being mounted in a heat receiving region of the linear conduit elements whereby longitudinal axes of the linear conduit elements are arranged in a first direction running through or being parallel to a plane defined by the heat exchange plate and wherein the at least one set of linear conduit elements extends beyond the heat receiving region on a first side and on an opposing second side in the first direction such that an extension of the at least one set of linear conduit elements on one of the first and second sides of the heat receiving region constitutes a condensing region for condensing a refrigerant vaporized in the heat receiving region in one of the first or second side that is arranged higher than the extension on the other side with respect to a direction of gravity in an operating state of the thermosyphon heat exchanger and wherein the extension of said other side constitutes a liquid reservoir whereby the at least one heat emitting device is thermally connected to the at least one heat exchange plate.

14. Power module according to claim 13 wherein the at least one heat emitting device comprises at least one of a power electronic device and a power electric device.

15. Thermosyphon heat exchanger according to claim 2, wherein the at least one set of linear conduit elements comprises a plurality of linear conduit elements, wherein an longitudinal axis of each linear conduit element of the at least one set of linear conduit elements is arranged in the first direction.

16. Thermosyphon heat exchanger according to claim 2, wherein the at least one set of linear conduit elements comprises at least a first manifold connecting first ends of the linear conduit elements and a second manifold connecting second ends of the linear conduit elements.

17. Thermosyphon heat exchanger according to claim 3, wherein the at least one set of linear conduit elements comprises at least a first manifold connecting first ends of the linear conduit elements and a second manifold connecting second ends of the linear conduit elements.

18. Thermosyphon heat exchanger according to claim 2, wherein the thermosyphon heat exchanger has fixing devices for fixing the thermosyphon heat exchanger, and the fixing devices being arranged symmetrically to a center point (C) of the thermosyphon heat exchanger.

19. Thermosyphon heat exchanger according to claim 3, wherein the thermosyphon heat exchanger has fixing devices for fixing the thermosyphon heat exchanger, and the fixing devices being arranged symmetrically to a center point (C) of the thermosyphon heat exchanger.

20. Thermosyphon heat exchanger according to claim 4, wherein the thermosyphon heat exchanger has fixing devices for fixing the thermosyphon heat exchanger, and the fixing devices being arranged symmetrically to a center point (C) of the thermosyphon heat exchanger.
